(19) United States
(12) Patent Application Publication
(10) Pub. No.: US 2025/0384941 A1
(43) Pub. Date: Dec. 18, 2025

(54) DYNAMIC START VOLTAGE (DSV) LEVEL-BY-LEVEL PROGRAMMING IN A MEMORY SUB-SYSTEM

(71) Applicant: Micron Technology, Inc., Boise, ID (US)

(72) Inventors: Huai-Yuan Tseng, San Ramon, CA (US); Eric Nien-Heng Lee, San Jose, CA (US); Koichi Kawai, Yokohama (JP); Akira Goda, Tokyo (JP); Yoshihiko Kamata, Yokohama (JP)

(21) Appl. No.: 19/236,223

(22) Filed: Jun. 12, 2025

Related U.S. Application Data
(60) Provisional application No. 63/660,407, filed on Jun. 14, 2024.

(51) Int. Cl. G11C 16/34

(52) U.S. Cl. CPC G11C 16/3459

(57) ABSTRACT

Control logic in a memory device causes a first program pulse of multiple program pulses to be applied to a first set of cells in a memory array. The first program pulse has a first program voltage. The control logic causes a first verify pulse of multiple verify pulses to be applied to the first set of memory cell responsive to applying a first program pulse to the first set of memory cells. The first verify pulse determines a first quantity of cells of the first set of cells that satisfy a program threshold. The control logic determines a second program voltage based on the first quantity of cells. The control logic causes a second program pulse to be applied to a second set of cells in the memory array. The second program pulse has the second program voltage.

### CLAIM OF PRIORITY

The present application claims the benefit under 35 U.S.C. § 119(e) of U.S. Provisional Patent Application No. 63/660,407 filed Jun. 14, 2024, which is incorporated by reference herein.

### TECHNICAL FIELD

Embodiments of the disclosure relate generally to memory sub-systems, and more specifically, relate to dynamic start voltage (DSV) for level-by-level programming in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system, according to some aspects of the disclosure.

FIG. 1B is a simplified block diagram of a first apparatus, in the form of a memory device, in communication with a second apparatus, in the form of a memory sub-system controller of a memory sub-system, according to some aspects of the disclosure.

FIG. 2 is a schematic of portions of an array of memory cells, such as a NAND memory array, according to some aspects of the disclosure.

FIG. 3 illustrates an example program operation for dynamic start voltage (DSV) level-by-level programming in a memory device of a memory sub-system, according to some aspects of the disclosure.

FIG. 4 is a flow diagram of an example method for dynamic start voltage (DSV) level-by-level programming in a memory device of a memory sub-system according to some aspects of the disclosure.

FIG. 5 is a flow diagram of an example method for dynamic start voltage (DSV) level-by-level programming in a memory device of a memory sub-system according to some aspects of the disclosure.

FIG. 6 is a block diagram of an example computer system in which embodiments of the disclosure may operate.

### DETAILED DESCRIPTION

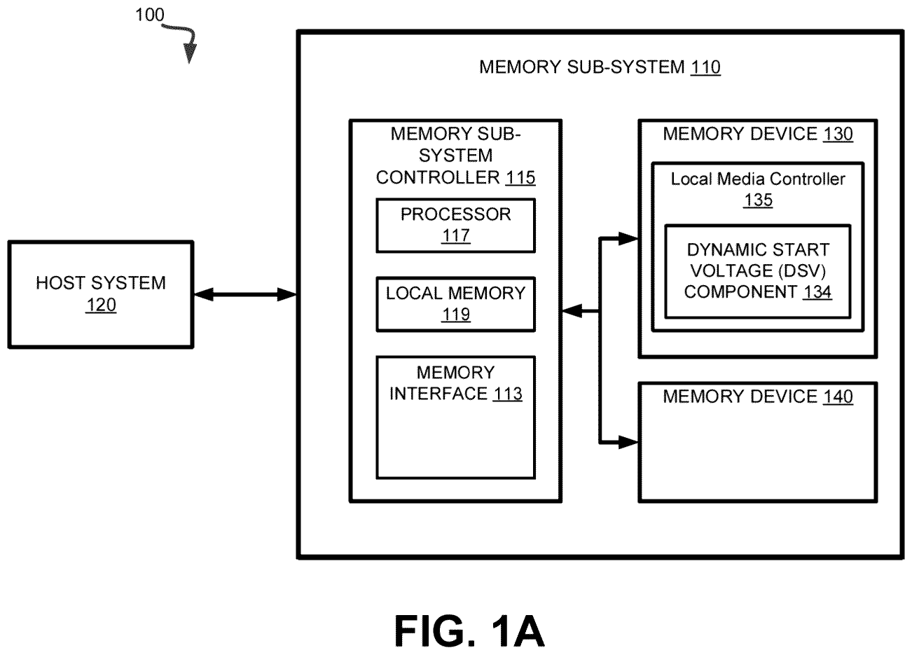

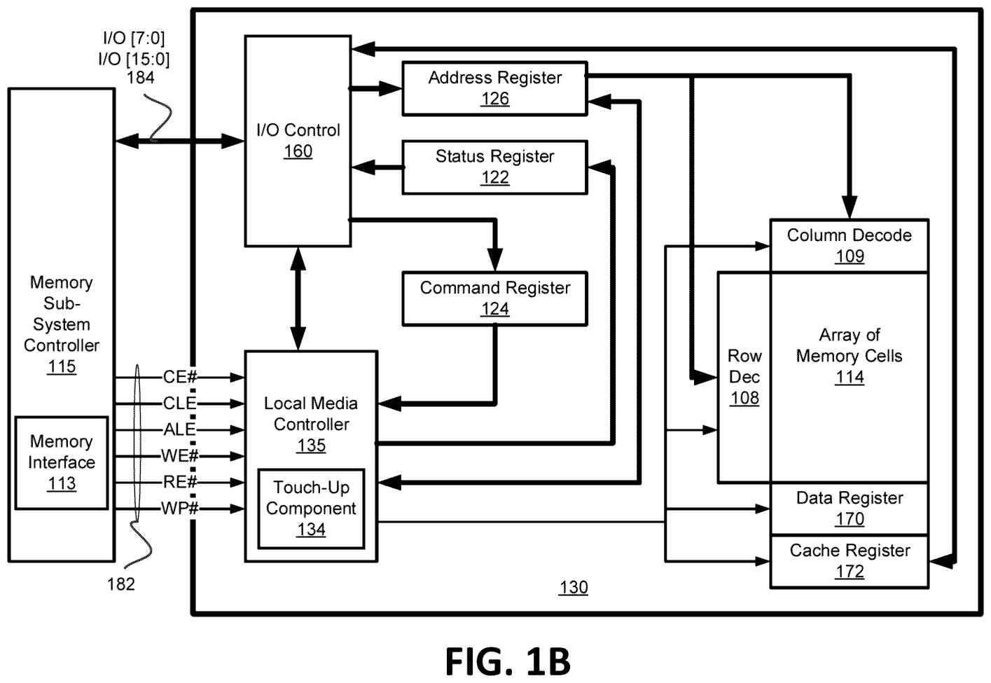

Aspects of the present disclosure are directed to dynamic start voltage (DSV) level-by-level programming in a memory device of a memory sub-system. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1A. A non-volatile memory device is a package of one or more dies. Each die can include of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

During certain memory access operations, selective slow program convergence (SSPC) can be used to improve a program threshold voltage distribution width (e.g., the width between voltage (Vt) distributions) on the memory device. In SSPC, or level-by-level programming, the memory cells are programmed with incrementally increased program pulses applied to wordlines to which the memory cells are coupled. After each program pulse, a program verify pulse determines a threshold voltage for the most recently programmed cell. As the threshold voltage for a particular cell approaches a desired voltage threshold, the bitline connected to the particular cell is biased with a voltage that slows down the change in the Vt of the cell. Cells without a biased bitline continue to be programmed at their normal pace. When the Vt for the cell reaches the desired voltage threshold, the bitline is biased with an inhibit voltage to prevent the Vt of the cell from continuing to change. To improve performance, an analog voltage may be applied to the bitlines connected to cells being programmed with SSPC.

After a level-by-level programming is performed, a touch-up program operation can be performed to narrow the respective voltage distributions of the programmed cells (e.g., increase the read-window budget (RWB)). In some touch-up program operations, program verify operations performed after program pulses can determine the threshold voltage for each previously programmed voltage distribution. For example, after a program pulse for a level three (L3) cell, the following program verify operation can include a first program verify pulse for the level one (L1) cell, a second program verify pulse for the level two (L2) cell, and a third program verify pulse for the level three (L3) cell. In this approach, performing program verifies for previously programmed cells during the touch-up program operation can substantially increase the overall programming time, and the duration between program pulses (especially for higher Vt distributions).

The start voltage for the program pulses can be based on a desired voltage corresponding to a threshold voltage of a voltage distribution. For example, to program a level one (L1) distribution, a program pulse can have a voltage value the same as, or greater than a threshold voltage for the L1 distribution. Subsequent program pulse voltages for subsequent level programming (e.g., level two (L2), level three (L3), up to level seven (L7), etc.) can each be separated by a constant voltage value. For example, the voltage value of the program pulse for L2, V2_{Program}, can be the voltage value of the program pulse for L1, V1_{Program} plus the constant program pulse difference value, V_{Constant}; in other words, V2_{Program}=V1_{Program}+V_{Constant}. By storing the start voltage for program pulses and a constant voltage value difference, memory needed to perform a level-by-level program operation is reduced. However, it can lead to over-programming or under-programming of a particular voltage distribution, resulting in a reduced RWB between certain distributions and an overall reduction in performance of the memory sub-system. The risk of over- or under-programming increases when this technique is applied to touch-up (e.g., “fine”) programming operations.

Aspects of the present disclosure address the above and other deficiencies by providing a memory sub-system that can implement a dynamic start voltage (DSV) for level-by-level programming in a memory device of a memory sub-system. The start voltage for each program pulse can be dynamically adjusted based on the voltage value of memory cells in a given voltage distribution. DSV can be used in an initial (e.g., primary) program operation, or in a touch-up (e.g., secondary) program operation to improve the RWB between voltage distributions of a memory device. By applying DSV to level-by-level primary and secondary programming operations, retention of data in the memory device can be improved. The DSV level-by-level program operation can perform a series of program pulses and corresponding sensing pulses. The sensing pulses can determine which memory cells associated with a voltage distribution have a voltage value below the voltage threshold associated with the voltage distribution. Based on the cells with voltage values below the voltage threshold associated with the voltage distribution (e.g., that do not satisfy a program threshold), a program voltage for a subsequent program pulse is determined. The program voltage can be used for an immediately subsequent program pulse, and/or for multiple subsequent program pulses.

Advantages of this approach include, but are not limited to, improved performance in the memory sub-system. The time and power required to perform program operations can be reduced. In addition, level-by-level touch-up programming can increase the RWB between the voltage distribution, resulting in, among other improvements, improved memory device stability and fewer errors over time.

FIG. 1A illustrates an example computing system 100 that includes a memory sub-system 110 in accordance with some aspects of the disclosure. The memory sub-system 110 can include media, such as one or more volatile memory devices (e.g., memory device 140), one or more non-volatile memory devices (e.g., the memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., the memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw the memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a memory interface component 113. Memory interface component 113 is responsible for handling interactions of the memory sub-system controller 115 with the memory devices of the memory sub-system 110, such as the memory device 130. For example, memory interface component 113 can send memory access commands corresponding to requests received from host system 120 to the memory device 130, such as program commands, read commands, or other commands. In addition, memory interface component 113 can receive data from the memory device 130, such as data retrieved in response to a read command or a confirmation that a program command was successfully performed. In some embodiments, the memory sub-system controller 115 includes at least a portion of the memory interface component 113. For example, the memory sub-system controller 115 can include a processor 117 (e.g., a processing device) configured to execute instructions stored in local memory 119 for performing the operations described herein. In some embodiments, the memory interface component 113 is part of the host system 120, an application, or an operating system.

In some embodiments, the memory device 130 includes the level-by level touch-up DSV component 134. The DSV component 134 is configured to carry out memory access operations in response to receiving memory access commands from the memory interface 113. In some embodiments, local media controller includes at least a portion of DSV component 134 and is configured to perform the functionality described herein. In some embodiments, DSV component 134 is implemented on the memory device 130 using firmware, hardware components, or a combination of the above.

In some embodiments, the DSV component 134 initiates a program operation on a the set of cells. The program operation can include sensing pulses and corresponding program pulses. The sensing pulses can determine a quantity of memory cells that satisfy a program threshold. The program pulses can be applied at a program voltage based on the quantity of memory cells that satisfy the program threshold. In some embodiments, the program operation can be initiated on a programmed set of cells (e.g., as a secondary, or “touch-up” program operation). In such embodiments, this series of verify pulses followed by touch-up program pulses can cause a previously programmed voltage distribution to narrow by increasing the voltage values of cells below a threshold voltage associated with a respective voltage distribution of the memory device, while cells with voltage values above the threshold voltage remain relatively constant (e.g., are inhibited from moving). In some embodiments, the DSV component 134 can work in conjunction with a programming component (not illustrated) to perform the touch-up program operation. In some embodiments, the DSV component 134 can include a timer or counter that is initialized when a particular wordline is programmed by a primary program operation. Once the timer or counter reaches a threshold (e.g., a number of intermediate program operations, duration of time since the primary program operation was performed, etc.), the DSV component 134 can initiate the secondary program operation on the particular wordline.

FIG. 1B is a simplified block diagram of a first apparatus, in the form of the memory device 130, in communication with a second apparatus, in the form of a memory sub-system controller 115 of a memory sub-system (e.g., memory sub-system 110 of FIG. 1A), according to some aspects of the disclosure. Some examples of electronic systems include personal computers, personal digital assistants (PDAs), digital cameras, digital media players, digital recorders, games, appliances, vehicles, wireless devices, mobile telephones, and the like. The memory sub-system controller 115 (e.g., a controller external to the memory device 130), may be a memory controller or other external host device.

The memory device 130 includes an array of memory cells (memory array 114) logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of the memory array 114 are capable of being programmed to one of at least two target data states.

Row decode circuitry 108 and column decode circuitry 109 are provided to decode address signals. Address signals are received and decoded to access the memory array 114. The memory device 130 also includes input/output (I/O) control circuitry 160 to manage input of commands, addresses and data to the memory device 130 as well as output of data and status information from the memory device 130. An address register 126 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the memory array 114 in response to the commands and generates status information for the memory sub-system controller 115, i.e., the local media controller 135 is configured to perform access operations (e.g., read operations, programming operations and/or erase operations) on the memory array 114. The local media controller 135 is in communication with row decode circuitry 108 and column decode circuitry 109 to control the row decode circuitry 108 and column decode circuitry 109 in response to the addresses. In one embodiment, local media controller 135 includes suspend DSV component 134.

The local media controller 135 is also in communication with a cache register 172. Cache register 172 latches data, either incoming or outgoing, as directed by the local media controller 135 to temporarily store data while the memory array 114 is busy writing or reading, respectively, other data. During a program operation (e.g., write operation), data may be passed from the cache register 172 to the data register 170 for transfer to the memory array 114; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the memory array 114, e.g., by sensing a state of a data line connected to that memory cell. A status register 122 may be in communication with I/O control circuitry 160 and the local media controller 135 to latch the status information for output to the memory sub-system controller 115.

The memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, the memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 126. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the memory array 114.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

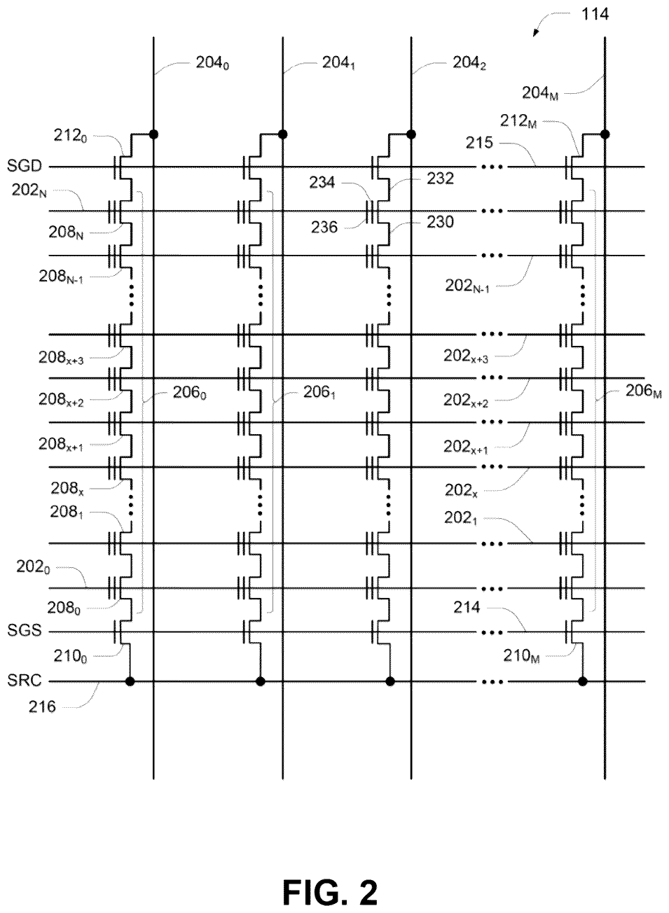

FIG. 2 is a schematic of portions of an memory array 114, such as a NAND memory array, as could be used in a memory of the type described with reference to FIG. 1B according to some aspects of the disclosure. Memory array 114 includes access lines, such as wordlines 202₀ to 202_{N}, and data lines, such as bit lines 204₀ to 204_{M}. The wordlines 202 can be connected to global access lines (e.g., global wordlines), not shown in FIG. 2, in a many-to-one relationship. For some embodiments, memory array 114 can be formed over a semiconductor that, for example, can be conductively doped to have a conductivity type, such as a p-type conductivity, e.g., to form a p-well, or an n-type conductivity, e.g., to form an n-well.

Memory array 114 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 114 in FIG. 2 can be a quasi-two-dimensional memory array and can have a generally planar structure, e.g., where the common source 216, NAND strings 206 and bit lines 204 extend in substantially parallel planes. Alternatively, the memory array 114 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the memory array 114 can be numbered consecutively from bit line 204₀ to bit line 204. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

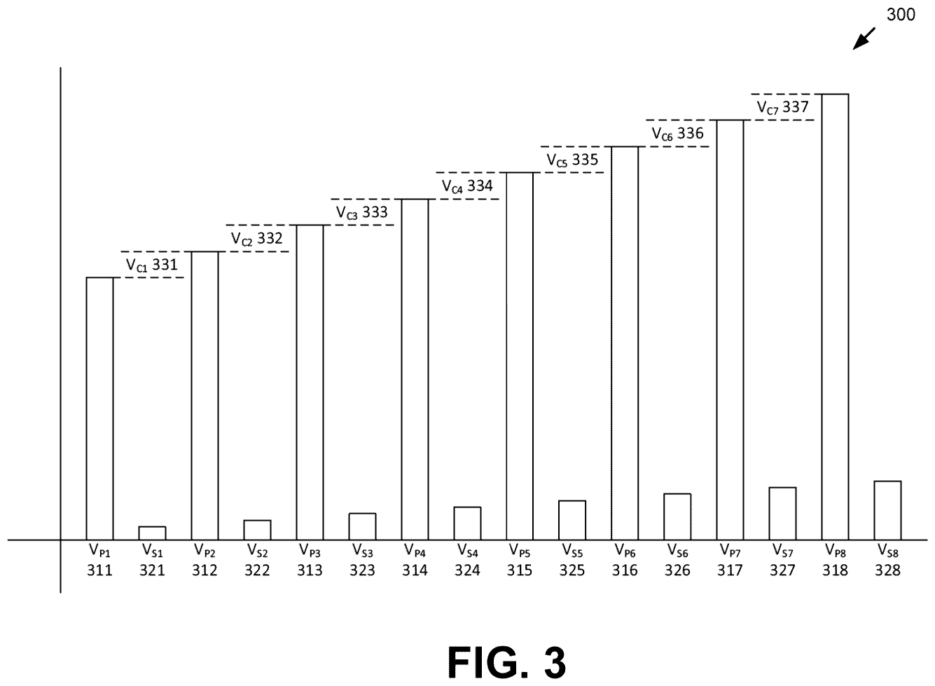

FIG. 3 illustrates an example program operation 300 for dynamic start voltage (DSV) level-by-level programming in a memory device of a memory sub-system, according to some aspects of the disclosure. Program operation 300 is illustrated in FIG. 3 as a program operation for a TLC memory device (i.e., a memory device having memory cells configured as TLC memory). It can be appreciated that similar program operations can similarly be performed on SLC-, MLC-, QLC-, and the like memory devices.

Program operation 300 includes program pulse 311 (V_{P1}) through program pulse 318 (V_{P8}), and verify pulse 321 (or sensing pulse) (V_{S1}) through verify pulse 328 (V_{S8}). In some embodiments, verify pulse 328 is optional. In some embodiments, (e.g., a secondary, or touch-up program operation) the program operation 300 begins with verify pulse 321 (e.g., a sensing pulse). Voltage change 331 (V_{C1}) through voltage change 337 (V_{C7}) represents a difference in the program voltage of respective program pulses. For example, voltage change 331 represents a difference in the program voltages of program pulse 311 and program pulse 312, voltage change 333 represents a difference in the program voltages of program pulse 313 and program pulse 314, and the like.

During a primary program operation, program pulses 311-318 can be applied to program certain memory cells to threshold voltages corresponding to respective voltage distributions. For example, program pulse 315 can be applied to program memory cells to a threshold voltage corresponding to a level four (L4) voltage distribution, and program pulse 316 can be applied to program memory cells to a threshold voltage corresponding to a level five (L5) voltage distribution. In some embodiments, the voltage values of the program pulses 311-318 can be greater than or equal to a desired voltage threshold corresponding to a respective voltage distribution. In the illustrated example for a TLC memory device, an initial pulse (e.g., program pulse 311) can be applied to sample the wordline to be programmed. Subsequent program pulses 312-218 can be applied to program memory cells to voltage distributions L1 through L7. Thus, in some embodiments, an initial sensing pulse (e.g., program pulse 311) and seven program pulses (e.g., program pulses 312-318) can be applied to program a group of memory cells in a memory array to the seven data-storing voltage distributions in a TLC memory device. In some embodiments, the program pulses 311-318 can be applied while an analog bitline voltage is applied to the memory cells being programmed.

During the primary program operation, verify pulses 321-328 can be applied to respective memory cells following a program pulse 311-318, as illustrated in FIG. 3. In some embodiments, the verify pulses 321-328 verify the success of a program pulse 311-318. For example, verify pulse 327, following program pulse 315 can verify that memory cells were programmed to a threshold voltage corresponding to a level six (L6) voltage distribution during the preceding program pulse 317. In some embodiments, the verify pulses 321-328 determine a quantity of memory cells that do not satisfy a program threshold. A program threshold can be satisfied for a memory cell when the voltage of the memory cell is similar to (e.g., slightly less than, the same as, or slightly greater than) a threshold voltage corresponding to a respective voltage distribution. In some embodiments, a quantity of memory cells that satisfy the program threshold can be referred to as passing bits. In some embodiments, a quantity of memory cells that satisfy the program threshold can be represented by the check-passed byte (CPByte) count and/or the check-passed bit (CPBit) count. CPByte can reflect the number of bytes in the sensed data that have at least one non-conducting bitline. In some embodiments, CPByte reflects the number of bytes in the sensed data where the last bitline of the byte a conducting bitline. In some embodiments, CPBit reflects the number of conducting bitlines in the sensed data.

During a secondary program operation, sensing pulses (e.g., verify pulses 321-328) can be applied to certain programmed memory cells (e.g., memory cells associated with a certain voltage distribution) to determine a quantity of memory cells that are at, or above a threshold voltage associated with the certain voltage distribution. For example, verify pulse 322 can be applied to memory cells associated with a level two (L2) voltage distribution to determine a quantity of cells that are greater than or equal to a threshold voltage of the L2 voltage distribution. In some embodiments, the quantity of memory cells that are greater than or equal to threshold voltage (e.g., quantity of memory cells that satisfy a program threshold) can be represented by a CPByte count and/or a CPBit count. The quantity of memory cells determined by the sensing pulse for memory cells of a first voltage distribution can be used to determine a program voltage of a program pulse for a second voltage distribution. For example, a verify pulse 323 can be applied to memory cells associated with a level three (L3) voltage distribution. A program voltage for a program pulse for a level four (L4) voltage distribution can be based on the quantity of memory cells that satisfy a program threshold of the L3 voltage distribution.

During the secondary program operation, program pulse 311 is not performed. Program pulses 312-318 can be applied to respective memory cells following the sensing pulses (e.g., verify pulses 321-328). In some embodiments, as described above, the program voltage of a program pulse can be based on a quantity of memory cells associated with a previous voltage distribution that satisfy a program threshold. In some embodiments, the program voltage of a program pulse can be based in part on an offset value.

When program voltages of program pulses 312-318 for primary program or secondary program operations are dynamically determined based on information about previously programmed memory cells (as described above), voltage changes 331-337 can each be unique. For example, voltage change 331 may not have the same value as voltage change 332 or voltage change 333. In some embodiments, the difference in program voltages between program pulses (e.g., the nominal values of voltage changes 331-337) can be based in part on a constant base voltage change. The base voltage change can be adjusted up or down responsive to information pertaining to previously programmed memory cells (e.g., as described above). In alternative embodiments, the difference in program voltages between program pulses (e.g., the nominal values of voltage changes 331-337) can be based on information obtained from previously programmed memory cells.

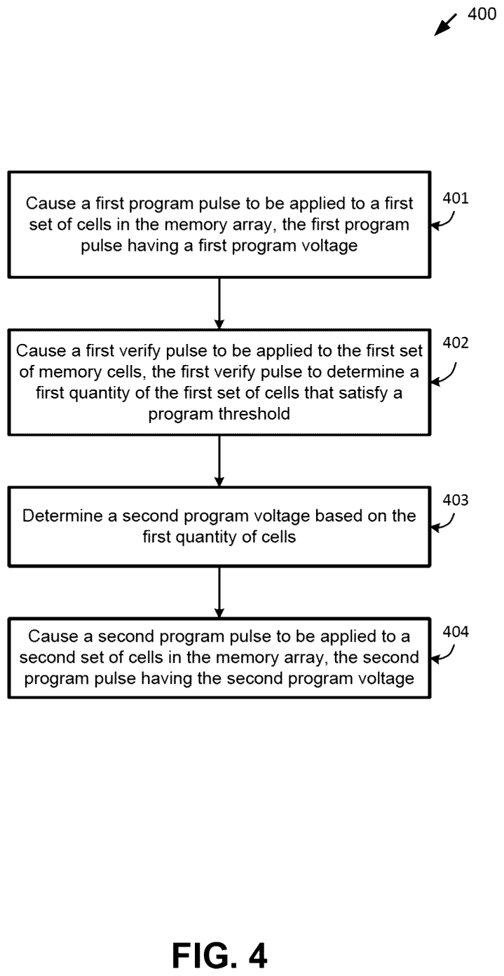

FIG. 4 is a flow diagram of an example method for level-by-level touch-up programming in a memory device of a memory sub-system in accordance with aspects of the disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the local media controller 135 and/or DSV component 134 of FIG. 1A. In some embodiments, the memory sub-system controller 115 and/or memory interface 113 of FIG. 1A can cause the method 400 to be performed (e.g., the method 400 can be caused to be performed). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 401, a program pulse is applied. For example, the processing logic (e.g., DSV component 134) can cause a program pulse having a first program voltage to be applied to a memory array, such as memory array 114 of the memory device 130. The first program pulse can be applied to a first set of memory cells. In some embodiments, the program pulse is a first program pulse of multiple program pulses. In some embodiments, the first program voltage is determined by a stored value. In some embodiments, the first program voltage can be determined based on physical characteristics (e.g., temperature) of the memory array 114 and/or memory device 130. In some embodiments, the first program voltage is determine based on one or more previously performed program pulses or program operations. As used herein, a program operation can include multiple program pulses.

At operation 402, a verify pulse is applied. For example, the processing logic causes a verify pulse to be applied to the memory array, such as memory array 114 of the memory device 130. In some embodiments, the verify pulse is a first verify pulse of multiple verify pulses. The verify pulse can be applied to the same set of memory cells as the most recent program pulse (e.g., a first set of memory cells). The verify pulse can determine a first quantity of a set of cells (e.g., the first set of memory cells) that satisfy a program threshold. As described above, the program threshold can refer to a threshold voltage for a particular voltage distribution, and a memory cell satisfies the program threshold if a voltage value of the memory cell is greater than or equal to the threshold voltage of the voltage distribution (e.g., a desired threshold voltage of the voltage distribution). In some embodiments, the verify pulse can determine a success of the program pulse. In some embodiments, information from the verify pulse can be graphically reflected as a voltage distribution (e.g., quantities of memory cells at each voltage value within the voltage distribution). A verify pulses can be performed after a programing pulse. For example, a primary program operation for a TLC memory device can have seven verify pulses-one verify pulse applied after each program pulse to program each of the voltage distributions (e.g., L1 through L7).

At operation 403, a program voltage is determined. For example, the processing logic can determine a second program voltage based on a quantity of cells in the first set of cells that satisfy the program threshold. In some embodiments, the quantity of cells can be represented as a CPBit count and/or CPByte count. If the quantity of cells is larger, the second program voltage can be smaller. Alternatively, if the quantity of cells is smaller, the second program voltage can be larger.

At operation 404, a second program pulse is applied. For example, the processing logic can cause a second program pulse having the second program voltage (e.g., of operation 403) to be applied to the memory array 114 of the memory device 130. The second program pulse can be applied to a second set of memory cells of the memory array. In some embodiments, additional program pulses can similarly be applied to additional sets of memory cells of the memory array. For example, a third program pulse can be applied to a third set of memory cells, etc. In some embodiments, the third program pulse can be applied at a third program voltage (e.g., determined with a second verify pulse, similar to operations 402 and 403). In alternative embodiments, the third program pulse can be applied at the second program voltage.

In some embodiments, the first program pulse applied to the first set of cells corresponds to a first voltage distribution, and the second program pulse applied to the second set of cells corresponds to a second voltage distribution. In some embodiments, the first voltage distribution and the second voltage distribution are adjacent. In alternative embodiments, the first voltage distribution and the second voltage distribution are not adjacent (e.g., they are separated by one or more voltage distributions). For example, a level one (L1) voltage distribution is adjacent to a level two (L2) voltage distribution, but an L1 voltage distribution is not adjacent to a level three (L3) voltage distribution (e.g., the L1 and L3 voltage distributions are separated by the L2 voltage distribution).

In some embodiments, operation 401 through operation 404 are performed in a primary program operation. That is, when memory cells are initially programmed. In some embodiments, operation 401 through operation 404 are repeated to perform a secondary program operation. The secondary program operation can be used to increase the RWB between voltage distributions and otherwise improve data retention properties of the memory device.

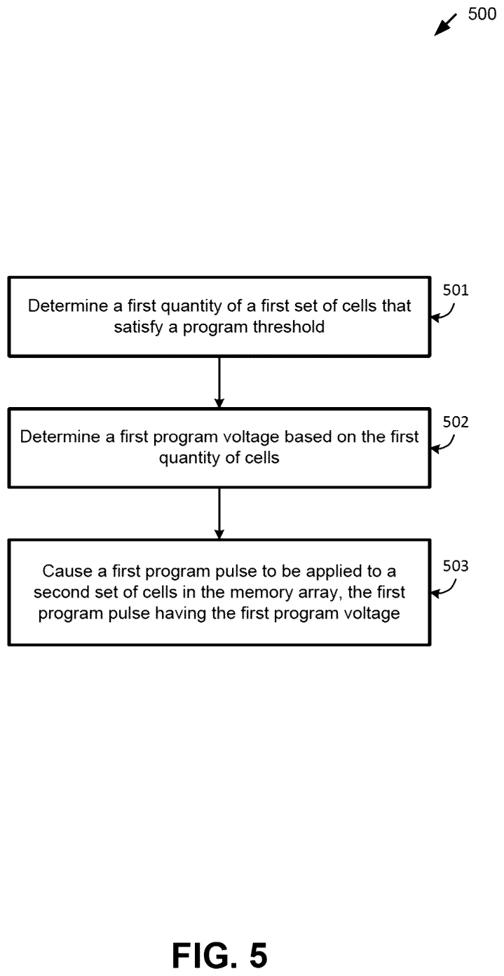

FIG. 5 is a flow diagram of an example method for dynamic start voltage (DSV) level-by-level programming in a memory device of a memory sub-system according to some aspects of the disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the local media controller 135 and/or DSV component 134 of FIG. 1A. In some embodiments, the memory sub-system controller 115 and/or memory interface 113 of FIG. 1A can cause the method 500 to be performed (e.g., the method 500 can be caused to be performed). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 501, a first quantity of cells is determined. For example, the processing logic (e.g., DSV component 134) can determine a first quantity of a first set of cells of the memory array 114 that satisfy a program threshold. In some embodiments, the processing logic can cause a first sensing pulse to be applied. For example, a first sensing pulse can be applied to the first set of cells of the memory array. The first sensing pulse can be used to determine a quantity of memory cells that satisfy the program threshold (e.g., the program threshold as described with reference to FIG. 3). In some embodiments, the first sensing pulse can be used to determine a quantity of memory cells having a voltage value that is greater than a threshold voltage of a voltage distribution associated with the first set of memory cells. In some embodiments, a first quantity of programmed memory cells (e.g., programmed cells) is determined. For example, the processing logic can determine a first quantity of a first set of programmed cells of the memory array that satisfy a program threshold. In some embodiments, the operation 501 can be performed as part of an initial, or primary program operation to program the memory array. In some embodiments, the operation 501 is performed as part of a refining, or secondary program operation to improve the readability (e.g., by increasing the RWB between voltage distributions) of memory cells in the memory array 114. In some embodiments, the quantity of cells is represented as a CPByte count or a CPBit count.

At operation 502, a first program voltage is determined. For example, the processing logic (e.g., DSV component 134) can determine a first program voltage based on the first quantity of cells of the first set of cells of the memory array 114 that satisfy the program threshold. In some embodiments, a program voltage is determined using a quantity of previously programmed memory cells for each program pulse of a program operation (e.g., a primary program operation or a secondary program operation). In some embodiments, a program voltage is determined using a quantity of previously programmed memory cells for certain program pulses of a program operation. For example, a program voltage can be determined using a first quantity of cells for a first program pulse and a fourth program pulse. The intervening second and third program pulses can be based on an offset value between program voltages, and/or base program voltages for each respective program pulse.

The value determined by the processing logic for the first program voltage can be inversely related to the first quantity of cells. For example, a higher quantity of cells indicates that more memory cells satisfy the program threshold, and thus that a lower program voltage can be used (e.g., the previous program pulse “overshot” the desired threshold voltage). In another example, a lower quantity of cells indicates that less memory cells satisfy the program threshold, and thus that a higher program voltage can be used (e.g., the previous program pulse “undershot” the desired threshold voltage).

In some embodiments, the first program voltage is determined based on the first quantity of cells. For example, if the first quantity of cells is larger, the processing logic can determine the first program voltage to be smaller. In another example, if the first quantity of cells is smaller, the processing logic can determine the first program voltage to be larger.

In alternative embodiments, the program voltage is determined using a base program voltage that is adjusted relative to the first quantity of cells. For example, if the first quantity of cells is larger the adjustment to the base program voltage is smaller, while if the first quantity of cells is smaller, the adjustment to the base program voltage is larger. In another example, if the first quantity of cells is larger, the base program voltage is adjusted down (e.g., the adjustment to the base program voltage is negative), while if the first quantity of cells is smaller, the base program voltage is adjusted up (e.g., the adjustment to the base program voltage is positive).

In another alternative embodiment, a program voltage is determined based on a previous program voltage, a program voltage offset, and the first quantity of cells. For example, the processing logic can identify a program voltage of a previous program pulse and a program voltage offset (e.g., a base offset value that is stored in the memory device). The processing logic can change the program voltage offset based on the first quantity of cells. For example, if the first quantity of cells is larger, the processing logic can decrease the size of the program voltage offset, resulting in a smaller program voltage when the program voltage offset is added to the previous program voltage. In another example, if the first quantity of cells is smaller, the processing logic can increase the size of the program voltage offset, resulting in a larger program voltage when the program voltage offset is added to the previous program voltage.

At operation 503, a program pulse is applied. For example, the processing logic can cause a first program pulse of the first program voltage to be applied to a second set of cells in the memory array. In some embodiments, the processing logic can cause a second program pulse of the first program voltage to be applied to a third set of cells in the memory array. In some embodiments, upon finishing the operation 503, the processing logic can return to the operation 501. That is, the processing logic can determine a second quantity of the second set of cells (e.g., the set of cells programmed during operation 503) that satisfy a program threshold associated with the second set of cells (e.g., a quantity of cells with voltages equal to or greater than a threshold voltage of a voltage distribution associated with the second set of cells). The processing logic can determine, based on the second quantity of cells, a second program voltage for a second program pulse. It will be appreciated that the use of “first,” “second,” “third,” and the like are used throughout this application to denote different instances of the same, or related objects or operations. The terms do not necessarily indicate a sequence (although they can, within context) nor do the terms indicate an original order. For example, a program operation can have multiple program pulses. The operations 501-503 can be performed on any of the multiple program pulses. Thus, for example, five program pulses of the program operation may have been performed before the “first” program pulse of operation 503 is caused to be performed.

In some embodiments, the first set of cells correspond to a first voltage distribution and the second set of cells correspond to a second voltage distribution. In some embodiments, the first voltage distribution and the second voltage distribution are adjacent. For example, the first set of cells can correspond to memory cells programmed to a level one (L1) voltage distribution and the second set of cells can correspond to memory cells programmed to a level two (L2) voltage distribution. In some embodiments, the first voltage distribution and the second voltage distribution are not adjacent (e.g., are separated by one or more voltage distributions). For example, the first set of cells can correspond to memory cells programmed to a level one (L1) voltage distribution and the second set of cells can correspond to memory cells programmed to a level five (L5) voltage distribution.

As described above, the operations 501-503 can similarly be applied to initial program operations (e.g., primary program operations) to store data to a memory device. In some embodiments, the operations 501-503 can be applied to refinement program operations (e.g., secondary program operations) to improve the stability and performance of a memory device (e.g., by increasing the RWB between voltage distributions). In some embodiments, the primary program operation can be separated in time from the secondary program operation. For example, a primary program operation can be performed on a set of cells based on the operations 501-503, and after a period of time, a secondary program operation can be performed on the set of cells based on the operations 501-503. In some embodiments, the difference in time between the primary program operation and the secondary program operation is based on a duration. In some embodiments, the difference in time between the primary program operation and the secondary program operation is based on a number of memory access operations (e.g., program operations). For example, the processing device can cause a primary program operation to be performed on a set of cells (or multiple sets of cells) then cause a certain quantity of memory access operations to be performed before causing a secondary program operation to be performed on the set of cells (or multiple sets of cells).

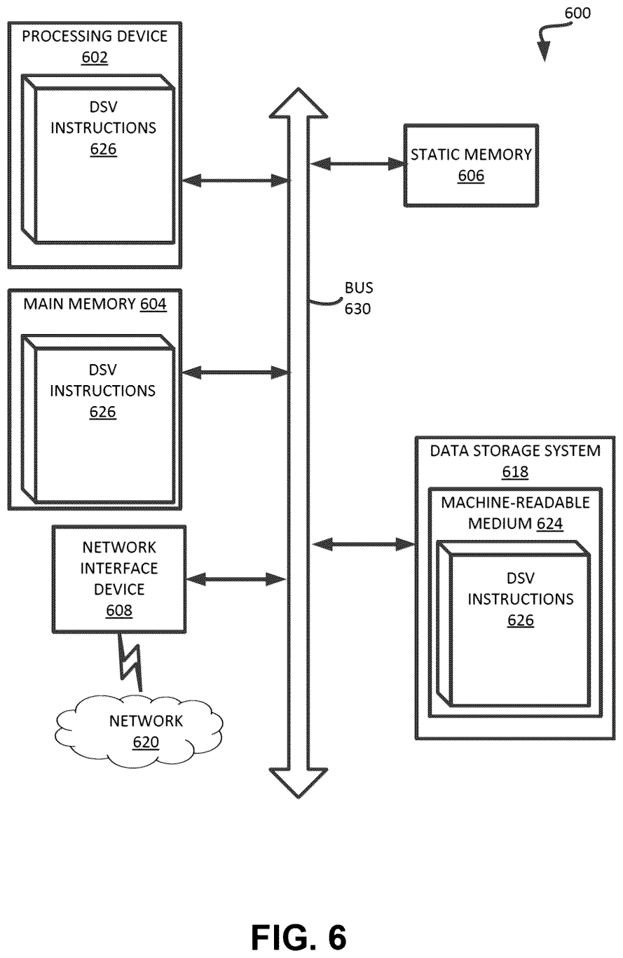

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute touch-up instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of touch-up instructions 626 or software embodying any one or more of the methodologies or functions described herein. The touch-up instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the touch-up instructions 626 include instructions to implement functionality corresponding to the local media controller 135 and/or the DSV component 134 of FIG. 1A. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells; and
control logic, operatively coupled with the memory array to perform operations comprising:
causing a first verify pulse of a plurality of verify pulses to be applied to a first set of memory cells responsive to applying a first program pulse to the first set of memory cells, the first verify pulse to determine a first quantity of cells of the first set of cells that satisfy a first program threshold;
determining a first program voltage based on the first quantity of cells; and
causing a second program pulse of a plurality of program pulses to be applied to a second set of cells of the plurality of cells in the memory array, the second program pulse having the first program voltage.

2. The memory device of claim 1, the operations further comprising:
causing a second verify pulse of the plurality of verify pulses to be applied to the second set of memory cells, the second verify pulse to determine a second quantity of cells that satisfy a second program threshold;
determining a third program voltage based on the second quantity of cells; and
causing a third program pulse to be applied to a third set of cells of the plurality of cells in the memory array, the third program pulse having the third program voltage.

3. The memory device of claim 1, the operations further comprising:
causing a third program pulse of the plurality of program pulses to be applied to a third set of memory cells in the memory array, the third program pulse having the second program voltage.

4. The memory device of claim 1, the operations further comprising:
causing a secondary program operation to be initiated on the memory array, the secondary program operation comprising:
causing a first sensing pulse of a plurality of sensing pulses to be applied to the first set of cells, the first sensing pulse to determine a second quantity of cells of the first set of cells that satisfy the first program threshold;
determining a first secondary program voltage based on the second quantity of cells; and
causing a first secondary program pulse to be applied to the first set of cells, the first secondary program pulse having the first secondary program voltage.

5. The memory device of claim 4, the operations further comprising:
causing a second sensing pulse of the plurality of sensing pulses to be applied to the second set of cells, the second sensing pulse to determine a third quantity of cells of the second set of cells that satisfy a second program threshold;
determining a second secondary program voltage based on the third quantity of cells; and
causing a second secondary program pulse to be applied to the second set of cells, the second secondary program pulse having the second secondary program voltage.

6. The memory device of claim 1, wherein the first set of cells correspond to a first voltage distribution and the second set of cells correspond to a second voltage distribution, and wherein the first voltage distribution is adjacent to the second voltage distribution.

7. The memory device of claim 1, wherein the first set of cells correspond to a first voltage distribution and the second set of cells correspond to a second voltage distribution, and wherein the first voltage distribution is separated from the second voltage distribution by one or more voltage distributions.

8. The memory device of claim 1, wherein the first quantity of cells of the first set of cells is a quantity of passing bits.

9. A method comprising:
causing a first sensing pulse of a plurality of sensing pulses to be applied to a first set of cells of a plurality of programmed memory cells of a memory array of a memory device responsive to applying a first program pulse to the first set of memory cells, the first sensing pulse to determine a first quantity of cells of the first set of cells that satisfy a first program threshold;
determining a second program voltage based on the first quantity of cells; and
causing a first program pulse of a plurality of program pulses to be applied to a second set of cells of the plurality of programmed memory cells in the memory array, the first program pulse having the first program voltage.

10. The method of claim 9, further comprising:
causing a second sensing pulse of the plurality of sensing pulses to be applied to the second set of memory cells, the second sensing pulse to determine a second quantity of cells of the second set of cells that satisfy a second program threshold;
determining a second program voltage of a third program pulse of the plurality of program pulses, the second program voltage based on the second quantity of cells; and
causing the third program pulse to be applied to a third set of cells in the memory array, the third program pulse having the second program voltage.

11. The method of claim 9, further comprising:
causing a third program pulse of the plurality of program pulses to be applied to a third set of memory cells in the memory array, the third program pulse having the first program voltage.

12. The method of claim 9, wherein the first set of cells correspond to a first voltage distribution and the second set of cells correspond to a second voltage distribution, and wherein the first voltage distribution is adjacent to the second voltage distribution.

13. The method of claim 9, wherein the first set of cells correspond to a first voltage distribution and the second set of cells correspond to a second voltage distribution, and wherein the first voltage distribution is separated from the second voltage distribution by one or more voltage distributions.

14. The method of claim 9, wherein the first quantity of cells of the first set of cells is a check passed byte count.

15. A memory device comprising:
a memory array comprising a plurality of memory cells; and
control logic, operatively coupled with the memory array to perform operations comprising:
determining a first quantity of cells of a first set of cells of the plurality of memory cells that satisfy a program threshold responsive to applying a first program pulse to the first set of memory cells;
determining a first program voltage based on the first quantity of cells; and
causing a second program pulse of a plurality of program pulses to be applied to a second set of cells of the plurality of memory cells in the memory array, the first program pulse having the first program voltage.

16. The memory device of claim 15, wherein the second set of cells are a second set of programmed memory cells programmed during a primary program operation, and the first program pulse is a secondary program pulse of a secondary program operation.

17. The memory device of claim 15, the operations further comprising:
causing a second program pulse to be applied to a third set of memory cells, the second program pulse having the first program voltage.

18. The memory device of claim 15, the operations further comprising:
causing a second sensing pulse to be applied to the second set of memory cells to determine a second quantity of cells that satisfy the program threshold;
determining a second program voltage based on the second quantity of cells; and
causing a second program pulse to be applied to a third set of memory cells of the plurality of memory cells in the memory array, the second program pulse having the second program voltage.

19. The memory device of claim 15, wherein the first set of cells correspond to a first voltage distribution and the second set of cells correspond to a second voltage distribution, and wherein the first voltage distribution is adjacent to the second voltage distribution.

20. The memory device of claim 15, wherein the first set of cells correspond to a first voltage distribution and the second set of cells correspond to a second voltage distribution, and wherein the first voltage distribution is separated from the second voltage distribution by one or more voltage distributions.
